(19) United States
(12) Patent Application Publication
(10) Pub. No.: US 2022/0223451 A1
(43) Pub. Date: Jul. 14, 2022

(54) SYSTEMS AND METHODS FOR TRANSFERRING DEVICES OR PATTERNS TO A SUBSTRATE

(71) Applicant: VueReal Inc., Waterloo (CA)

(72) Inventor: Hameed TALEBI, Waterloo (CA)

(73) Assignee: VueReal Inc., Waterloo, ON (CA)

(21) Appl. No.: 17/613,286

(22) PCT Filed: May 22, 2020
(86) PCT No.: PCT/IB2020/054908

§ 371 Date: Nov. 22, 2021

Related U.S. Application Data
(60) Provisional application No. 62/851,188, filed on May 22, 2019.

(51) Int. Cl. H01L 21/68

(52) U.S. Cl. CPC H01L 21/681; H01L 25/075; H01L 21/682

(57) ABSTRACT

The present disclosure relates to transferring system and methods and more specifically to transferring multiple patterns or devices from a transfer medium to a substrate. The transferring apparatus comprising a first holder to hold a substrate, a second holder to hold a transfer medium, wherein the transfer medium comprises one of a: device or pattern, a first alignment system coupled to the second holder while the second holder moves in a first direction relative to one dimension of the substrate to transfer the device or the pattern; and a second alignment system coupled to the second holder while the second holder moves in a second direction relative to another dimension of the substrate to transfer the device or the pattern to the substrate, wherein the transferring apparatus is operable to transfer a plurality of devices and patterns to the substrate.

### CROSS-REFERENCE TO RELATED APPLICATION

This application claims benefit of and priority to U.S. Patent Application No. 62/851,188, filed May 22, 2019, which is hereby incorporated by reference herein in its entirety.

### FIELD OF THE INVENTION

The present disclosure relates to transferring systems and methods and more specifically fix transferring multiple patterns or devices from a transfer medium to a substrate.

### BACKGROUND

Many micro devices including light emitting diodes (LEDs), organic LEDs (OLEDs), sensors, solid state devices, integrated circuits, MEMS (micro-electro-mechanical systems), and other electronic components are typically fabricated in batches, often on a donor substrate or planar substrate. During micro device fabrication on the donor substrate, various patterning techniques may be employed that require a plurality of complex and costly photolithography steps which also require a perfect pattern transfer to the substrate.

Furthermore, to form an operational system, micro devices from at least one donor substrate need to be selectively transferred to a receiver substrate. During transfer, the donor substrate and the receiver substrate need to be aligned.

In general, transfer machines have two main axial motions that cause relative motion of cartridge wafers and display panel wafers for dimensional inaccuracy, Also, all mechanical motions have errors and have a level of inaccuracy.

Therefore, there is a need for a method and system to efficiently transfer patterns or devices on a transfer medium to substrates and also measure the inaccuracies and compensate for errors between the two.

### SUMMARY

An object of the present invention is to overcome the shortcomings of the prior art by providing a transfer system and method to transfer multiple devices or patterns from a transfer medium to a substrate.

According to one embodiment, a transferring apparatus may be provided. The transferring apparatus may comprise a first holder to hold a substrate, a second holder to hold a transfer medium, wherein the transfer medium comprises one of a device or a pattern, a first alignment system coupled to the second holder while the second holder moves in a first direction relative to one dimension of the substrate to transfer the device or the pattern; and a second alignment system coupled to the second holder while the second holder moves in a second direction relative to another dimension of the substrate to transfer the device or the pattern to the substrate, wherein the transferring apparatus is operable to transfer a plurality of devices and patterns to the substrate.

According to another embodiment, a method to transfer a device or a pattern to a substrate may be provided. The method may comprising providing a first holder to hold a substrate, providing a second holder to hold a transfer medium, wherein the transfer medium comprises one of the device or the pattern, moving the second holder in a first direction relative to one dimension of the substrate to transfer the device or the pattern, moving the second holder in a second direction relative to another dimension of the substrate to transfer the device or the pattern to the substrate; and repeating the transferring steps to transfer a plurality of devices and patterns to the substrate.

According to one embodiment, the substrate may be a backplane wafer/receiver substrate and the transfer medium may be a cartridge wafer/donor substrate with at least one micro device or a mask with a pattern.

According to some embodiments, a method of transferring devices or patterns to a substrate may be provided. The method may comprise providing a first holder to hold the substrate, wherein the substrate has at least a first and a second dimension, providing a second holder to hold a transfer medium, wherein the transfer medium comprises at least one of a device or a pattern, providing a first and a second alignment system, calibrating a position of the second alignment system with the position of the second holder, loading the substrate in the first holder and the transfer medium in the second holder, aligning the transfer medium and the substrate at an edge of the substrate related to the first dimension through the first alignment system, transferring a plurality of devices or patterns to the substrate, moving the first holder or substrate relative to the second dimension; and keeping the substrate and the second holder in alignment using the second alignment system and the position calibration information.

The foregoing and additional aspects and embodiments of the present disclosure will be apparent to those of ordinary skill in the art in view of the detailed description of various embodiments and/or aspects, which are made with reference to the drawings, a brief description of which is provided next.

### BRIEF DESCRIPTION OF THE DRAWINGS

The foregoing and other advantages of the disclosure will become apparent upon reading the following detailed description and upon reference to the drawings.

FIG. 1 shows a schematic sectional view of a transferring apparatus, in accordance with an embodiment of the present invention.

FIG. 2 shows another schematic sectional view of a transferring apparatus, in accordance with an embodiment of the present invention.

FIG. 3 shows a side view of a positional drift in an angle measured by a profilometer, in accordance with an embodiment of the present invention.

FIG. 4 is a flowchart illustrating a transferring process.

Use of the same reference numbers in different figures indicates similar or identical elements.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed, Rather, the disclosure covers all modifications, equivalents, and alternatives falling within the spirit of the invention as defined by the appended claims.

### DETAILED DESCRIPTION

While the present teachings are described in conjunction with various embodiments and examples, it is not intended that the present teachings be limited to such embodiments. On the contrary, the present teachings encompass various alternatives and equivalents, as will be appreciated by those of skill in the art.

In this description, “system substrate”, “receiver substrate” and “display substrate” are used interchangeably. However, it is clear to one skilled in the art that the embodiments described here are independent of substrate type.

In this description, the terms “donor substrate”, “carrier substrate”, and “cartridge substrate’” are used interchangeably. However, it is clear to one skilled in the art that the embodiments described here are independent of substrate type.

In this description, the terms “wafer” and “substrate” are used interchangeably.

Some embodiments of the present invention are related to a transfer system and method to transfer multiple devices or patterns from a transfer medium to a substrate.

In general, a transferring apparatus/transfer machine has two linear motions (e.g., X-axis and Y-axis). The transferring apparatus may comprise a first holder to hold a first wafer/substrate, a second holder to hold a second wafer/mask, a first and a second alignment systems, optical encoders installed on a first and a second direction of the apparatus, a profilometer to measure a surface profile and an angle of the second wafer relative to the first wafer, a hexapod to align the transfer medium relative to the substrate and a plurality of cameras to measure the location of fiducial marks on the second wafer and the first wafer to measure the relative location of both the wafers. The cameras may be precise machine vision cameras that measure the inaccuracies and compensate for errors between two wafers.

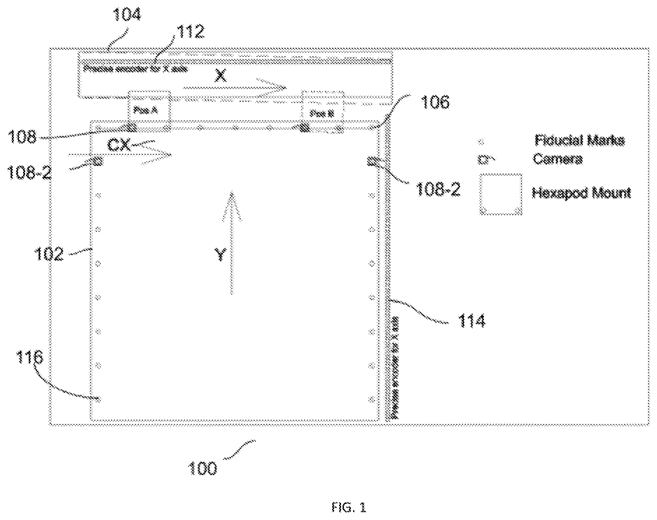

FIG. 1 shows a schematic sectional view. of a transferring apparatus in accordance with an embodiment of the present invention.

Here, a transferring apparatus 100 may be provided. The transferring apparatus may comprise a first holder 102 to hold a substrate and a second holder 104 to hold a transfer medium. The first holder 102 may be provided on a second direction of the transferring apparatus. The second holder 104 may be provided on a first direction of the transferring apparatus. In one case, the first direction and the second direction may also be referred to as the x axis and y-axis, respectively, of the transferring apparatus.

In one case, the substrate may be a backplane wafer/receiver substrate and the transfer medium may be a cartridge wafer/donor substrate with at least one micro device or a mask with a pattern.

In one embodiment, there may be provided precise encoders (112, 114) on both the first and second directions of the transferring apparatus. The precise encoder 112 on the first direction may be used to measure course travel of the second holder carrying transfer medium. The precise encoder 114 on the second direction may be used to measure course travel of the first holder carrying substrate.

In one embodiment, a first and a second alignment system may be provided and coupled to the second holder to move the transfer medium relative to the substrate. A detection device such as a profilometer may be used to scan the substrate and the transfer medium to determine relative flatness or offset the substrate relative to the transfer medium.

The second holder 104 carrying transfer medium may be moved to the start of the first direction and the first holder 102 carrying substrate may move to the start of the second direction. The transfer medium may be picked from the second holder using a vacuum on a positioning system (e.g., a hexapod). The positioning system may be mounted on the side of the apparatus and coupled to the second holder, with a moving platform to hold the transfer medium for movement with six degrees of freedom.

In another embodiment, one or more fiducials or alignment marks 116 may be provided on the substrate and the transfer medium.

In one embodiment, one or more vision systems coupled to the first and second holder to capture the alignment marks, wherein the alignment marks are provided on both the substrate and the transfer medium.

In another embodiment, one or more stationary vision systems 108-2 relative to the first holder may be provided. The two stationary vision systems are fixed and mounted at both sides of the first holder to capture an image of the alignment marks on two sides of the substrate.

In yet another embodiment, at least one moving vision system 108 may be provided. The moving cameras 108 may be mounted at the top of the second holder to capture an image of the alignment marks on the transfer medium and at a horizontal edge of the substrate to measure a relative location of both.

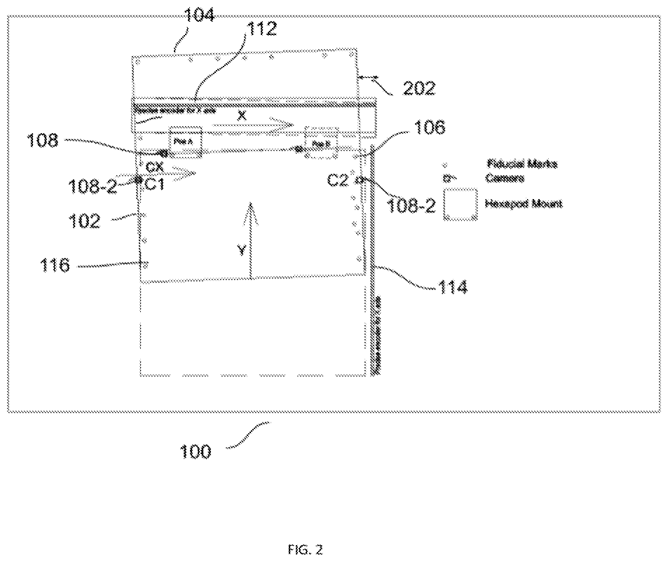

FIG. 2 shows another diagrammatic view of a sample transfer process for a transfer machine in accordance with an embodiment of the present invention in which the second holder moves relative to the substrate to transfer the device or the pattern to the substrate. FIG. 2 uses the same reference numbers for identical elements used in FIG. 1.

As a result of manufacturing errors in the design of holders, the alignment marks of both the substrate and the transfer medium may not align and as a consequence, angular and positional deviation may occur in both the substrate and the transfer medium.

Here, as shown in FIG. 2, the fixed side cameras 108-2 are mounted to check the position of the alignment marks 106 on the substrate and the moving camera 108 checks the position of the alignment marks on the transfer medium and at a horizontal edge of the substrate to measure a relative location of both.

According to one embodiment, using course travel and hexapod, the transfer medium first alignment mark may be brought into the moving camera 108 field to capture position A, and then move to a second alignment mark to capture position B. In one case, at least two known alignment marks on a transfer medium wafer may be captured. The location of the alignment marks may determine the coordinates of the first and second directions of the transfer medium.

In one case, the transfer substrate may be removed out of the moving camera field of view after capturing the alignment marks of the transfer medium, but may be moved into a known nesting location.

Furthermore, the different alignment marks of the substrate may be brought into the fixed camera 108-2 field of view (e.g., C1 and C2) and the moving camera 108 field of view all at once. Each alignment marks position of the substrate may be captured and compared with the transfer medium alignment marks positions. By comparing the positions of alignment marks, an appropriate deviation or offset (i.e., offset in all directions first, second, third, rotation, tip, tilt) may be calculated.

In one embodiment, at least one detection system may be provided, the detection system may detect an angular deviation/offset of the substrate relative to the transfer medium in communication with the vision system. In one case, the detection system comprises a profilometer. The profilometer (not shown in figures) may measure angular errors caused by manufacturing error of the holder. The profilometer may be mounted at one side of the transferring apparatus.

Then, the moving camera may be moved back to its home position. In one example, it may be moved out of the operating area.

Now, the second holder moves relative to another dimension of the substrate to transfer the device or the pattern to the substrate and compensate for all calculated alignment offsets (i.e., offset in all directions X, Y, Z, rotation, tip, tilt).

In some embodiments, the at least one positioning system may be provided. The positioning system may be configured to position the substrate with respect to the transfer medium based on the angular deviation so that the substrate alignment marks are aligned with the transfer medium alignment marks. In one case, the positioning system may comprise a hexapod. The positioning system is configured to provide six degrees of freedom alignment. For illustration purposes, only one positioning system is provided. However, there may be more than one positioning system as per the design requirements.

After the first alignment is completed, the substrate moves in the second direction. The fixed cameras continue to capture the alignment marks on the display substrate as it moves in a second direction. All of the transferring steps may be repeated to transfer a plurality of devices and patterns to the substrate.

In one case, the rotation of the display substrate can be calculated and compensated for using cartridge template motion as the display substrate continues to travel.

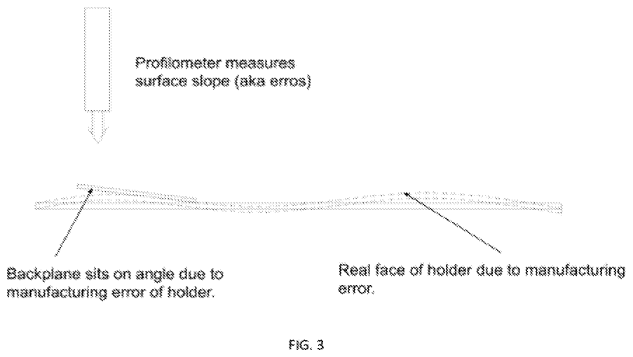

FIG. 3 shows a side view of positional drift in an angle measured by a profilometer in accordance with an embodiment of the present invention. The profilometer is mounted at the side of the transferring apparatus to measure a positional drift in an angle of the substrate relative to the transfer medium.

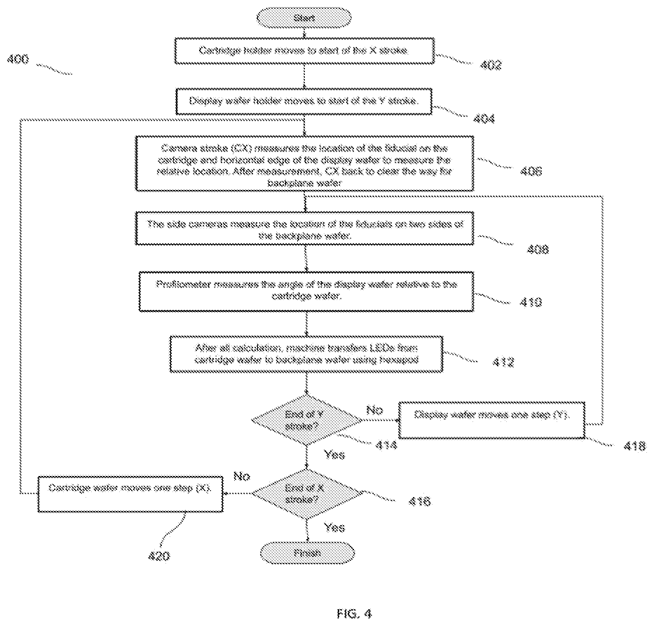

FIG. 4 shows a flowchart of a method to transfer between the cartridge, wafer and the display wafer in a transfer machine in accordance with an embodiment of the present invention. The method 400 comprises steps that may be completed in any particular order to achieve a desired state.

Method 400 may begin in block 402. In block 402, a second holder 102 of FIG. 1 used to hold a mask or transfer medium may be moved to the start of a first direction of the transferring apparatus. In block 404, a first holder 104 of FIG. 1 used to hold a substrate may move to the start of the second direction.

According to one embodiment, the substrate may be a backplane wafer or receiver substrate and the transfer medium may be a cartridge wafer or donor substrate with at least one micro device, or a mask with a pattern.

A plurality of cameras 106 as shown in FIG. 1 may be provided to measure the locations of the fiducial marks on, wafers/carriers in both the first and second directions. The camera may include but is not limited to high precision machine cameras. In block 406, camera stroke (CX) may measure the location of fiducial marks on the transfer medium and the horizontal edge of the substrate to measure the relative location. After measurement, the camera stroke may move back to clear the way for the backplane wafer.

There may be cameras 106-2 located on the sides of the display, wafers. In the next step 408, the side cameras measure the location of the fiducials on two sides of the backplane wafer. In a further step 410, a profilometer may be used to measure the angle of the display wafer relative to the cartridge wafer.

In step 412, after all the calculations, the machine transfers the LEDs from the cartridge, wafer to the backplane wafer using the hexapod. In step 414, if the second direction stroke ends, one may check if the first direction stroke ends at step 416, in case the second direction stroke does not end at step 414, the display wafer may move one step at 418 and in case there is no first direction stroke end at step 416, the cartridge wafer may move one step in the first direction in step 420. The process may be finished if both the first and second direction strokes end.

In another embodiment, a method of transferring devices or patterns to a substrate may be provided. The method may comprise providing a first holder to hold the substrate, wherein the substrate has at least a first and a second dimension, providing a second holder to hold a transfer medium, wherein the transfer medium comprises at least one of a device or a pattern, providing a first and a second alignment system, calibrating a position of the second alignment system with the position of the second holder, loading the substrate in the first holder and the transfer medium in the second holder, aligning the transfer medium and the substrate at an edge of the substrate related to the first dimension through the first alignment system, transferring a plurality of devices or patterns to the substrate, moving the first holder or substrate relative to the second dimension; and keeping the substrate and the second holder in alignment using the second alignment system and the position calibration information.

According to one embodiment, a transferring apparatus may be provided. The transferring apparatus may comprise a first holder to hold a substrate, a second holder to hold a transfer medium, wherein the transfer medium comprises one of a: device or pattern, a first alignment system coupled to the second holder to move the second holder in a first direction relative to one dimension of the substrate to transfer the device or the pattern; and a second alignment system coupled to the second holder to move the second holder in a second direction relative to another dimension of the substrate to transfer the device or the pattern to the substrate, wherein the transferring apparatus is operable to transfer a plurality of devices and patterns to the substrate.

According to another embodiment, the transferring apparatus may further comprising one or more vision systems coupled to the first and second holder to capture alignment marks, wherein the alignment marks are provided on the substrate and the transfer medium, at least one detection system that detects an angular deviation of the substrate relative to the transfer medium; and at least one positioning system configured to position the transfer medium with respect to the substrate based on the angular deviation.

According to yet another embodiment, the transferring apparatus may further comprise at least one encoding unit mounted along both the first holder and the second holder to determine an exact position of the substrate and the transfer medium on the alignment system, wherein the first holder is movable along the second direction of the transferring apparatus.

According to some embodiments, the one or more vision systems may comprise stationary and moving cameras. The moving vision system is mounted at the top of the second holder to capture an image of the alignment marks on the transfer medium and at a horizontal edge of the substrate to measure a relative location of both. The two stationary vision systems may be fixed and mounted at both sides of the first holder to capture an image of the alignment marks on two sides of the substrate. The stationary and moving vision systems both may comprise precise machine vision cameras.

According to further embodiments, the detection system may comprise a profilometer and the positioning system may comprise a hexapod. The substrate comprises one of a: display wafer, backplane wafer, or growth substrate and the transfer medium comprises one of a: cartridge, wafer, donor wafer, or mask.

According to one embodiment, a method to transfer a device or a pattern to a substrate may comprising providing a first holder to hold a substrate, providing a second holder to hold a transfer medium, wherein the transfer medium comprises one of the device or the pattern, moving the second holder in a first direction relative to one dimension of the substrate to transfer the device or the pattern, moving the second holder in a second direction relative to another dimension of the substrate to transfer the device or the pattern to the substrate; and repeating the transferring steps, a)-d) to transfer a plurality of devices and patterns to the substrate.

According to yet another embodiment, the method may further comprise providing a first alignment system and a second alignment system coupled to the second holder to move the second holder in the first and the second direction, respectively. The device may be a micro light emitting device.

According to some embodiments, a method of transferring devices or patterns to a substrate may be provided. The method may comprise providing a first holder to hold the substrate, wherein the substrate has at least a first and a second dimension, providing a second holder to hold a transfer medium, wherein the transfer medium comprises at least one of a device or a pattern, providing a first and a second alignment system, calibrating a position of the second alignment system with the position of the second holder, loading the substrate in the first holder and the transfer medium in the second holder, aligning the transfer medium and the substrate al an edge of the substrate related to the first dimension through the first alignment system, transferring a plurality of devices or patterns to the substrate, moving the first holder or substrate relative to the second dimension; and keeping the substrate and the second holder in alignment using the second alignment system and the position calibration information.

According to another embodiment, the method may further comprise, providing one or more vision systems coupled to the first and second holder to capture alignment marks, wherein the alignment marks are provided on the substrate and the transfer medium and providing at least one detection system that detects an angular deviation of the substrate relative to the transfer medium.

The foregoing description of one or more embodiments of the invention has been presented for illustration and description purposes. It is not intended to be exhaustive or to limit the invention to the precise film disclosed. Many modifications and variations are possible in light of the above teachings. It is intended that the scope of the invention be limited not by this detailed description, but rather by the appended claims.

1. A transferring apparatus comprising:
a first holder to hold a substrate;
a second holder to hold a transfer medium, wherein the transfer medium comprises one of a: device or pattern;
a first alignment system coupled to the second holder to move the second holder in a first direction relative to one dimension of the substrate to transfer the device or the pattern; and
a second alignment system coupled to the second holder to move the second holder in a second direction relative to another dimension of the substrate to transfer the device or the pattern to the substrate, wherein
the transferring apparatus is operable to transfer a plurality of devices and patterns to the substrate.

2. The transferring apparatus of claim 1, further comprising:
one or more vision systems coupled to the first and second holder to capture alignment marks, wherein the alignment marks are provided on the substrate and the transfer medium.

3. The transferring apparatus of claim 1, further comprising:
at least one detection system configured to detect an angular deviation of the substrate relative to the transfer medium; and
at least one positioning system configured to position the transfer medium with respect to the substrate based on the angular deviation.

4. The transferring apparatus of claim 1, further comprising:
at least one encoding unit mounted along both the first holder and the second holder to determine an exact position of the substrate and the transfer medium on the alignment system.

5. The transferring apparatus of claim 1, wherein the first holder is movable along the second direction of the transferring apparatus.

6. The transferring apparatus of claim 2, wherein the one or more vision systems comprise stationary and moving cameras.

7. The transferring apparatus of claim 6, wherein the moving vision system is mounted at the top of the second holder to capture an image of the alignment marks on the transfer medium and at a horizontal edge of the substrate to measure a relative location of both.

8. The transferring apparatus of claim 6, wherein two stationery vision systems are fixed and mounted at both sides of the first holder to capture an image of the alignment marks on two sides of the substrate.

9. The transferring apparatus of claim 1, wherein the stationary and moving vision systems both comprise precise machine vision cameras.

10. The transferring apparatus of claim 3, wherein the detection system comprises a profilometer.

11. The transferring apparatus of claim 3, wherein the positioning system comprises a hexapod.

12. The transferring apparatus of claim 1, wherein the substrate comprises one of a: display wafer, backplane wafer, or growth substrate.

13. The transferring apparatus of claim 1, wherein the transfer medium comprises one of a: cartridge wafer, donor wafer, or mask.

14. A method to transfer a device or a pattern to a substrate comprising:
a) providing a first holder to hold a substrate;
b) providing a second holder to hold a transfer medium, wherein the transfer medium comprises one of the device or the pattern;
c) moving the second holder in a first direction relative to one dimension of the substrate to transfer the device or the pattern;
d) moving the second holder in a second direction relative to another dimension of the substrate to transfer the device or the pattern to the substrate; and
repeating the transferring steps, a)-d) to transfer a plurality of devices and patterns to the substrate.

15. The method of claim 14, further comprising:
providing a first alignment system and a second alignment system coupled to the second holder to move the second holder in the first and the second direction, respectively.

16. The method of claim 14, wherein the device is a micro light emitting device.

17. A method of transferring devices or patterns to a substrate comprising:
a) providing a first holder to hold the substrate, wherein the substrate has at least a first and a second dimension;
b) providing a second holder to hold a transfer medium, wherein the transfer medium comprises at least one of a device or a pattern;
c) providing a first and a second alignment system;
d) calibrating a position of the second alignment system with the position of the second holder;
e) loading the substrate in the first holder and the transfer medium in the second holder;
f) aligning the transfer medium and the substrate at an edge of the substrate related to the first dimension through the first alignment system;
g) transferring a plurality of devices or patterns to the substrate;
h) moving the first holder or substrate relative to the second dimension; and
i) keeping the substrate and the second holder in alignment using the second alignment system and the position calibration information,

18. The method of claim 17, further comprising:
providing one or more vision systems coupled to the first and second holder to capture alignment marks, wherein the alignment marks are provided on the substrate and the transfer medium.

19. The method of claim 17, further comprising:
providing at least one detection system that detects an angular deviation of the substrate relative to the transfer medium.
